(19) United States
(12) Patent Application Publication
(10) Pub. No.: US 2026/0190345 A1
(43) Pub. Date: Jul. 2, 2026

(54) STACKED EMBEDDED MEMORY ARRAY WITH NARROW LOGIC-TO-MEMORY TRANSITION REGION

(71) Applicant: Intel Corporation, Santa Clara, CA (US)

(72) Inventors: Joseph D’Silva, Hillsboro, OR (US); Christopher Neumann, Portland, OR (US); Shriram Shivaraman, Portland, OR (US); Sou-Chi Chang, Portland, OR (US); Uygar E. Avci, Portland, OR (US); Nazila Haratipour, Portland, OR (US)

(73) Assignee: Intel Corporation, Santa Clara, CA (US)

(21) Appl. No.: 19/002,289

(22) Filed: Dec. 26, 2024

(51) Int. Cl. H10B 53/20; H10B 53/30; H10B 53/40; H10B 53/50

(52) U.S. Cl. CPC H10B 53/20; H10B 53/30; H10B 53/40; H10B 53/50

(57) ABSTRACT

Integrated circuit (IC) devices having transition regions between logic and memory regions. An IC device may include interconnect lines through a dielectric material in interconnect layers over a device layer, a stack of memory cells over the device layer and laterally adjacent the interconnect layers, a conductor extending vertically through the memory cells, a distance shorter than a height of the stack of memory cells separating the stack of memory cells and a sidewall of the dielectric material, and lateral surfaces of the memory cells not vertically aligned with lateral surfaces of any of the interconnect lines. A chemically metallic sidewall layer may enable a dielectric-on-dielectric process that negates the need for a large transition region between logic and memory regions.

### BACKGROUND

In conventional integrated circuit (IC) devices, memory cells are often stacked in arrays and embedded over a device layer, next to interconnect layers for logic regions. To fabricate stacked arrays not constrained by (e.g., vertically aligned with) the dimensions of the adjacent logic interconnect layers, the region occupied by the memory array is cleared (e.g., etched) out, and the memory stacks are typically formed from alternating, conformal scaffolding and releasable layers. This results in a wasteful transition region framing the memory region, where the transition region around the memory arrays has a width on the order of (e.g., more than a tenth of) the height of the memory stacks. Additionally, removing the conformal alternating layers from the transition region requires etch and polish steps with challenging uniformity and selectivity requirements.

New techniques, structures, and materials are needed to improve area utilization in ICs having embedded stacks of memory cells.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views of an integrated circuit (IC) device having a narrow transition region between interconnect layers in a logic region and stacks of memory cells in a memory region, in accordance with some embodiments;

FIG. 2 is a flow chart of methods for forming a memory region with embedded memory stacks and a narrow transition region between the memory region and an adjacent logic region, in accordance with some embodiments;

FIGS. 3A, 3B, 3C, 3D, 3E, 3F, 3G, 3H, 3I, 3J, and 3K illustrate profile views of an IC device having a memory region with stacks of memory cells and a narrow transition region between logic and memory regions, at various stages of manufacture, in accordance with some embodiments;

FIGS. 4A, 4B, 4C and 4D illustrate profile views of an IC device having a thinner transition region between interconnect layers in a logic region and stacks of memory cells in a memory region, at various stages of manufacture, in accordance with some embodiments;

FIGS. 5A, 5B, 5C, and 5D illustrate profile views of an IC device having a thinner transition region between interconnect layers in a logic region and stacks of memory cells in a memory region, at various stages of manufacture, in accordance with some embodiments;

FIG. 6 illustrates a diagram of an example data server machine employing an IC device having narrow transition regions between logic and memory regions, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures, materials, and techniques are disclosed to improve area utilization in integrated circuit (IC) devices having stacked memory arrays embedded adjacent logic regions.

The scaffolding for an embedded memory stack may be built up using a dielectric-on-dielectric (DoD) process following the deposition of (chemically) metallic sacrificial sidewalls in an opening etched in an interconnect stack. In the DoD process, an area-selective deposition of a stack of dielectric layers will be built up on exposed dielectric surfaces. The metallic sidewalls may provide non-preferential growth surfaces that do not interfere with the stack up of dielectric layers from a floor of an etched-out memory region. The sacrificial sidewalls may be deployed instead of stacks of multiple scaffolding and releasable layers that waste area due to necessarily having the same thicknesses as the layers used for (and between) the stacked memory cells. Forgoing multiple, thick sidewall layers enables more efficient use of die area and reduces distances to peripheral circuits, and the consequently shorter routing to the circuitry offers power and performance benefits. Additionally, the single sacrificial sidewall layers may be removed much more simply and cheaply than the stacks of scaffolding and releasable layers typically used, for example, without polishing operations or challenging uniformity or selectivity requirements.

The sacrificial sidewalls may be deposited as a thin film material that behaves (chemically) as a metal for the DoD process employed for forming the memory stack scaffold. The thin film need not be as thick as the layers in the memory stack or scaffold. The reduced process complexity of stacked embedded memory array fabrication may reduce manufacturing costs and increase yields. Yields may be increased by failure reductions, as well as more efficient area utilization. Performance may be increased by shorter routing to peripheral circuitry and concomitant lower power consumption.

By using only the single, thin-film sacrificial sidewall, the width of the transition region between the logic and memory regions may be significantly reduced. The sacrificial (e.g., chemically metallic) sidewall may be replaced by a dielectric material, forming a dielectric structure between the logic and memory regions, spanning both above and below the memory-cell stacks in the memory region. In many embodiments, a stack of memory cells and the dielectric material of an adjacent interconnect layer (e.g., isolation between adjacent interconnect lines and vias) are separated by a distance less than the height of the memory stack. In some embodiments, the sacrificial sidewall is isotropically etched before replacement by a dielectric material, which may reduce a width of the transition region. In some embodiments, a dielectric sidewall layer is on the sacrificial, metallic sidewall layer (to protect the sacrificial sidewall during a clearing-out of the bottom of the memory region, for example), and the dielectric layer has thickness less than half the thickness of the metallic layer, which may result in a reduced transition-region width. In some embodiments, the stack of memory cells and the dielectric material of the adjacent interconnect layer (e.g., isolating adjacent interconnect lines and vias) are separated by a distance less than half the height of the memory stack. By decoupling the transition-region width from the memory-stack height, the novel process described may enable taller memory stacks, for example, of more memory cells in the same die area.

The embedded memory stacks described may be on either or both of back or front sides of IC substrates. Since memory cell layer heights no longer need to be aligned with interconnect layer heights, the clear-out etch of the memory region spans fewer layers on the back side compared to the front side for same vertical height of the memory array.

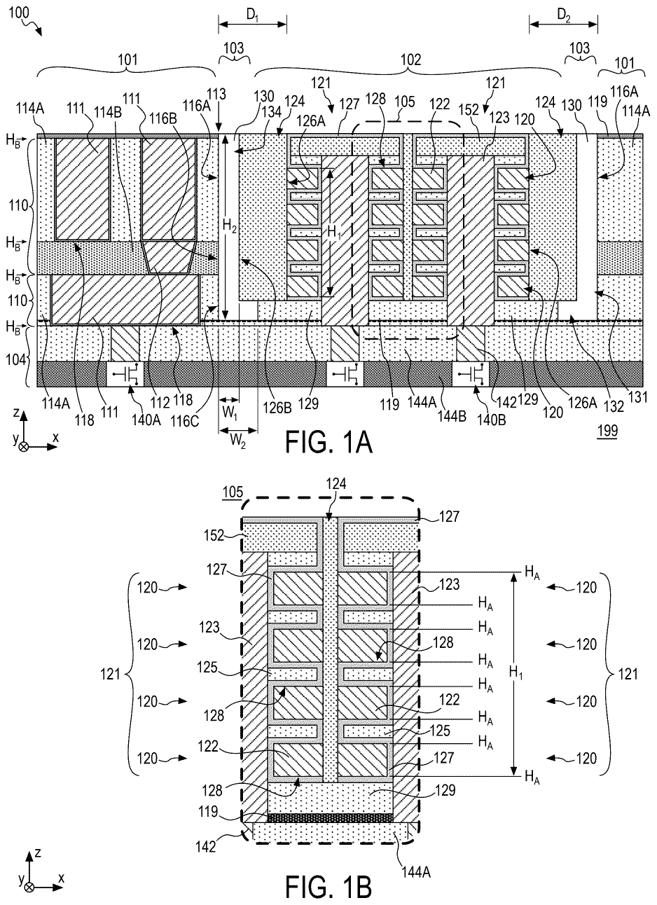

FIGS. 1A and 1B illustrate cross-sectional profile views of an IC device 100 having a narrow transition region 103 between interconnect layers 110 in a logic region 101 and stacks 121 of memory cells 120 in a memory region 102, in accordance with some embodiments. FIG. 1A shows regions 101, 102, 103 over a device layer 104 and includes a view 105 (delineated with a dashed box) of memory region 102. FIG. 1B illustrates a magnified view 105, e.g., with greater detail of portions of region 102, for example, memory cells 120.

As shown in FIG. 1A, logic region 101 includes multiple interconnect layers 110 over device layer 104. Layers 110 include at least one dielectric material 114 and one or more interconnect lines 111 and via 112 extending through material(s) 114. In the exemplary embodiment of FIG. 1A, lines 111 in an upper layer 110 extend through a dielectric material 114A in the y-dimension and lines 111 in a lower layer 110 extend through dielectric material 114A in the x-dimension. In the exemplary embodiment of FIG. 1A, lines 111 extending through dielectric material 114A in an upper layer 110 and lines 111 extending through dielectric material 114A in a lower layer 110 are separated by a dielectric material 114B. Vias 112 couple between orthogonal lines 111 in vertically adjacent layers 110. Other vias (not shown, e.g., behind the x-z viewing plane of FIG. 1A) may contact lines 111 in an upper layer 110 through an upper etch-stop layer above layer 110. Interconnect lines 111 have lateral surfaces 118 at vertical positions H_{B}.

Interconnect lines 111 and vias 112 may be conductive (e.g., metal) structures that couple device layer 104 to other, upper interconnect layers, e.g., to one or more power supplies (such as V_{DD} and V_{SS}). Metallization lines 111 and vias 112 may include any suitable material(s). Lines 111 and vias 112 may include the same or different material(s). In many embodiments, lines 111 and vias 112 include one or more of copper, gold, tantalum, cobalt, tungsten, ruthenium, molybdenum, aluminum, and nickel, including in alloys. In some embodiments, lines 111 and vias 112 include nitrides of metals, e.g., tantalum and titanium. Lines 111 and vias 112 may include other electrically conductive materials, including non-metals.

Logic region 101 abuts transition region 103 at a border 113 of logic region 101. Border 113 includes sidewall 116B of dielectric material 114B between sidewalls 116A, 116C of dielectric materials 114A. Dielectric materials 114A, 114B may be the same or different dielectric materials 114. Dielectric materials 114A, 114B are advantageously low-k (low-permittivity) materials 114, for example, to provide electrical isolation between adjacent lines 111 and vias 112. Interconnect layers 110 may include or contact other dielectric layers, e.g., etch-stop layers 119 above and/or below dielectric materials 114 in layers 110.

Memory region 102 is over device layer 104 and laterally adjacent logic region 101. Memory region 102 includes a dielectric material 124 and stack 121 of memory cells 120. Cells 120 may store bits of data as a charge on or across electrodes 122, 123. Dielectric material 124 is to both sides of stack 121 of memory cells 120 and between stacks 121. Dielectric material 124 advantageously is or includes a low-k material, for example, to provide electrical insulation between stacks 121 of cells 120 and adjacent structures, including other stacks 121. Dielectric material 124 has sidewalls 126 (e.g., sidewalls 126A, 126B). Sidewall 126A is on stack 121 of memory cells 120. Dielectric material 124 and cells 120 meet at shared sidewall 126A. Dielectric material 124 (e.g., sidewall 126A) is on sidewall 126A of stack 121 of memory cells 120 and dielectric layers 125. Sidewall 126B is adjacent logic region 101. Electrode 123 extends vertically through (and forms part of each of) memory cells 120.

Multiple stacks 121 of memory cells 120 and dielectric layers 125 are over device layer 104. Stacks 121 are vertically aligned arrays of cells 120. Memory region 102 may include an array of stacks 121, e.g., arranged in a grid extending in the x-and y-dimensions. Each stack 121 of memory cells 120 has a height H₁ spanning from a bottom or lower lateral surface 128 of a lowermost cell 120 of the stack 121 to a top or upper lateral surface 128 of an uppermost cell 120 of the stack 121. Although stacks 121 are all shown having four vertically aligned cells 120, stacks 121 may have any suitable array size, such as six cells 120, eight cells 120, etc.

Stack 121 of memory cells 120 and dielectric layers 125 is laterally adjacent interconnect layers 110. In each stack 121, multiple, vertically aligned outer electrodes 122 are to both sides of (e.g., encircling) a shared, center electrode 123. Memory cells 120 include outer and inner electrodes 122, 123 and an insulator layer 127 between electrodes 122, 123. Each cell 120 includes an outer electrode 122 and a corresponding portion of electrode 123. As in the exemplary embodiment of FIG. 1A, a single insulator layer 127 may be continuous throughout a stack 121 of cells 120. Portions of the multiple stacks 121 and cells 120 are shown in greater detail at FIG. 1B.

Dielectric layers 125 are interleaved with memory cells 120 in stack 121, with a layer 125 between each pair of vertically adjacent cells 120. As well as memory cells 120, electrode 123 extends vertically through dielectric layers 125. Electrode 123 extends vertically through dielectric layer 129 under stacks 121. A dielectric layer 152 may be over each electrode 123.

Dielectric layer 129 is in memory region 102, over device layer 104 and between device layer 104 and stack 121 of memory cells 120 and layers 125. Dielectric layer 129 extends laterally beyond sidewalls 126A of memory cells 120 and stacks 121. Layer 129 is between logic region(s) 101. Dielectric layer 129 is between structures 130. In the exemplary embodiment of FIG. 1A, layer 129 does not extend laterally beyond dielectric material 124; dielectric material 124 extends laterally beyond dielectric layer 129. Dielectric layers 125, 129 are advantageously low-k dielectric material(s) of the same or different compositions. In many embodiments, layers 125, 129 include silicon and oxygen (e.g., in an oxide of silicon, such as silicon dioxide, SiO₂).

The material(s) of insulator layer 127 may be any suitable (e.g., dielectric) material, for example, a ferroelectric material that enables the storing of information as a residual, e.g., non-volatile, charge on electrodes 122, 123. Memory cells 120 with a ferroelectric layer 127 may be ferroelectric capacitors with layer 127 between plate electrodes 122, 123.

As in FIG. 1A, ferroelectric layer 127 may include a material in a ferroelectric phase (orthorhombic, non-centrosymmetric crystallinity), which may be exhibited by a higher relative permittivity. For example, a high-k (high-permittivity) dielectric including predominantly hafnium and oxygen (HfOₓ), but not in a ferroelectric phase, may have a relative permittivity in the range of 10-14. However, hafnium oxide in a ferroelectric phase may have a relative permittivity exceeding 25 (e.g., 30). Although in both instances, the oxide includes predominantly hafnium and oxygen, ferroelectric layer 127 advantageously includes a ferroelectric phase of a material, e.g., hafnium oxide. In the case of hafnium oxide (and other pertinent metal oxides, as described below), such phases may be achieved, for example, through the addition of a dopant, such as niobium, titanium, silicon, germanium, aluminum, yttrium, etc.

Many ferroelectric materials are suitable for use in ferroelectric layer 127. As used herein, the term ferroelectric material indicates a material that has a spontaneous electric polarization that may be controlled by the application of an external electric field. Ferroelectric materials exhibit a hysteresis such that when a positive voltage is applied, a positive residual charge is maintained even as the voltage falls to zero. This residual charge is characterized as polarization. To remove the polarization, a negative voltage may be applied. Furthermore, the negative voltage may be used to provide a negative polarization, which is also maintained as the voltage again goes to zero. In ferroelectric cells 120 discussed herein, a differential voltage may be applied across ferroelectric capacitor plate electrodes 122, 123 to polarize the ferroelectric material (e.g., ferroelectric layer 127) either positively or negatively. This positive or negative polarity may then be read as 1 or 0. Besides the advantage of higher relative permittivity, ferroelectric materials and this polarization have this non-volatility advantage over non-ferroelectric dielectric materials.

Any suitable ferroelectric material may be used. In some embodiments, ferroelectric layer 127 include materials having perovskite structures, e.g., PZT (lead zirconium titanate, e.g., PbZrₓTi₁₋ₓO₃). Perovskite materials have the general formula ABX₃ and may be in a structure deviated from a cubic structure. While both A and B are positively charged ions, they may be of different sizes with the A atoms generally larger than the B atoms. The X is a negatively charged ion (frequently an oxide) that bonds to both A and B cations. These perovskite structures can include compounds where the A and/or B sites include multiple materials (e.g., A1ₓ₋₁A2ₓ and/or B1_{y-1}B2_{y}). The X site may deviate from, e.g., a cubic coordination configuration as ions within the A and B sites undergo changes in their oxidation states. In some embodiments, ferroelectric layer 127 include materials other than PZT but with perovskite structures.

Advantageously, ferroelectric layer 127 includes a ferroelectric material that may be deposited conformally and to very narrow thicknesses, such as a two-dimensional (2D) material. Such is the case with numerous oxides of hafnium or similar metals. In some embodiments, ferroelectric layer 127 includes hafnium, zirconium, and oxygen (HZO) (e.g., hafnium zirconium oxide, Hf₁₋ₓZrₓO₂). In some such embodiments, ferroelectric layer 127 includes dopants, e.g., titanium or niobium. In some embodiments, ferroelectric layer 127 includes hafnium, titanium, and oxygen (e.g., hafnium titanium oxide, Hf₁₋ₓTiₓO₂). In some embodiments, ferroelectric layer 127 includes hafnium, scandium, and oxygen. In some embodiments, ferroelectric layer 127 includes zirconium and oxygen (e.g., zirconium dioxide, ZrO₂). In some embodiments, ferroelectric layer 127 includes niobium and oxygen.

Although, e.g., hafnium zirconium oxide or doped HfOₓ or ZrOₓ are exemplary embodiments that can be advantageously conformally deposited by atomic layer deposition (ALD), ferroelectric layer 127 may also have other compositions similarly amenable to being deposited at temperatures compatible with, e.g., back-end-of-line (BEOL) structures and with similar thickness conformality. Compositions compatible with BEOL process may enable the formation of memory cells 120 and stacks 121 over device layers 104, for example, within front-or back-side interconnect layers 110. Other ferroelectric or non-ferroelectric materials may be deployed in layer 127, including materials other than oxides.

In some embodiments, layer 127 has a wurtzite crystalline structure. In some embodiments, layer 127 includes aluminum, scandium, and nitrogen (e.g., aluminum scandium nitride, AlₓSc₁₋ₓN, which may be aluminum nitride doped with scandium). Aluminum scandium nitride may advantageously be conformally deposited by ALD, as a 2D material, and at low temperatures (e.g., <250°C), which provides compatibility with BEOL flows. Other ferroelectric materials may be employed.

Memory cells 120 (and dielectric layers 125) need not be fabricated with the dielectric layers 110 and materials 114. Memory cells 120 are not vertically aligned with any of the one or more interconnect lines 111. For example, the lateral (e.g., upper and lower) surfaces of memory cells 120 are at vertical positions not aligned with (e.g., at a same height as) any vertical positions H_{B} of lateral surfaces 118 of any of interconnect lines 111. That cells 120 and lines 111 do not need to be aligned may be enabled by a fabrication process of stacks 121 that is independent of the formation of layers 110 in regions 101.

Transition region(s) 103 separate logic and memory regions 101, 102. Region(s) 103 includes a dielectric material 134 in dielectric structure(s) 130 between dielectric materials 114, 124. Together, dielectric structure 130 and dielectric material 124 (and distance D₁ spanning structure 130 and material 124) separate stack 121 (e.g., at sidewall 126A) and logic region 101 (e.g., at sidewall 116 of dielectric material 114). In the exemplary embodiment of FIG. 1A, dielectric structure 130 separates dielectric materials 114, 124 and has a height H₂ greater than height H₁ of stack 121 of memory cells 120. In some embodiments, height H₂ spans from below a bottom of a lowermost of a pair of interconnect layers 110 to above a top of an uppermost of the pair of interconnect layers 110.

Regions 102, 103 may be symmetric between regions 101 and layers 110. For example, symmetric dielectric structures 130 and regions 103 may bookend region 102, between regions 101, 102. Region(s) 103 and dielectric structure(s) 130 (and material 134) may be on and between dielectric materials 114, 124 on both sides of region 102 (and on all other sides of region 102, e.g., in front of and behind). (Region 103 may be continuous on all sides of and around region 102.) On both sides of region 102, sidewalls 126A of stacks 121 of cells 120 and sidewalls 116 (e.g., sidewalls 116A, 116C) of material 114 may be separated by equal distances D₁, D₂. In many embodiments, memory region 102 is surrounded by a single transition region 103 between region 102 and a single logic region 101 surrounding region 102. For example, a single dielectric structure 130 of material 134 may frame around regions 102, separating regions 101, 102.

Transition region 103 has a width W₁ (or a width W₂) between regions 101, 102. In many embodiments, as in the exemplary embodiment of FIG. 1A, dielectric structure 130 includes continuous vertical and horizontal portions 131, 132. Vertical portion 131 is between and in contact with both dielectric materials 114, 124. Horizontal portion 132 is in contact with dielectric layer 129 and dielectric material 124. Dielectric structure 130 has a width W₁ (e.g., of portion 131) separating sidewall 116 of dielectric material 114 and sidewall 126 of dielectric material 134. Dielectric structure 130 has a width W₂ (e.g., of portion 132) separating dielectric layer 129 (under dielectric material 124) and sidewall 116 of dielectric material 114. A distance D₁ separates sidewall 126A of stack 121 of memory cells 120 and border 113 of logic region 101 (e.g., sidewall 116 of dielectric material 114). Distance D₁ includes width W₁ of portion 131 of structure 130 and a lateral width (e.g., in the x-dimension) of dielectric material 124.

Transition region 103 need not include area enough (e.g., linear distance in the x-dimension) to accommodate conformal deposition (including laterally, in the x-dimension) of a layer stack for forming stack 121. In many embodiments, region 103 has a width W₁ less than half of height H₁ of stack 121. In many embodiments, region 103 has a width W₂ less than half of height H₁ of stack 121. In many embodiments, distance D₁ is shorter than height H₁ of stack 121. These relatively small dimensions (of widths W₁, W₂ and distance D₁) may be enabled by a fabrication process of stacks 121 that does not depend on the lateral deposition (e.g., building up on and from sidewalls) of a conformal-layer stack used to form stacks 121. These relatively small dimensions (of widths W₁, W₂ and distance D₁) advantageously enables more efficient use of die area and reduces distances to peripheral circuits. The consequently shorter routing to the peripheral circuitry offers power and performance benefits, such as reduced dissipation of signal power and reduced line parasitics. In some embodiments, distance D₁ (between stack 121 of memory cells 120 (e.g., sidewall 126A) and sidewall 116 of dielectric material 114) is less than half of height H₁ of stack 121, which may offer yet further power and performance benefits.

Memory region 102, logic region(s) 101, and transition region(s) 103 are over device layer 104, for example, built up over layer 104 on a front or back side of substrate 199. In some embodiments, regions 101, 102, 103 are on both front and back sides of substrate 199. Device layer 104 may be or include a layer 144B of semiconductor material (such as silicon, etc.) under (and/or between) interconnect layers 110 in substrate 199. Device layer 104 includes transistor structures 140 (represented by schematic symbols) in layer 144B, which may also include dielectric material, etc. Interconnect lines 111 and vias 112 may be coupled to logic transistor structures 140A in device layer 104, and memory cells 120 may be coupled to select transistor structures 140B in device layer 104. Device layer 104 may include other structures 140, and structures 140 (e.g., structures 140A, 140B) may have various structures and functions.

Parallel rows (or columns) of stacks 121 may be accessed by select transistor structures 140B on parallel or orthogonal wordlines below, for example, and (e.g.) written to (or read from) bitlines above. Transistor structures 140 may be coupled with regions 101, 102 above layer 104 by lines or vias 142 through dielectric layer 144A. In some embodiments, lines or vias 142 are interconnect lines 111 and vias 112 in a dielectric layer 110 between regions 101, 102 and device layer 104 (and layer 144B of layer 104). Lines or vias 142 may be of any suitable materials, e.g., those described of lines 111 and vias 112. In some embodiments, interconnect layers 110 (in regions 101) and embedded memory stacks 121 (in regions 102) are on both of back and front sides of IC device 100 and substrate 199.

Substrate 199 may include any suitable material or materials. Substrate 199 may be an IC substrate, such as an IC die or wafer. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a base layer 144B of semiconductor material) that other materials (such as metals and dielectrics) are built up on. In some contexts, substrate 199 may refer to a base material layer 144B and any build-up layers 110, etc., over the base.

In many embodiments, many materials (e.g., dielectric materials 114, 124 and layers 119, 125, 129, 144A, 152) include silicon. For example, low-k materials (e.g., dielectric materials 114, 124) may include silicon and oxygen. Some adjacent (e.g., abutting) materials may have at least slightly different compositions (e.g., including nitrogen and/or carbon in addition to, or instead of, oxygen), for example, to provide etch selectivities. Layers 119 may provide good etch selectivities with adjacent materials, e.g., dielectric materials 114, and may be of any suitable material(s), such as silicon and nitrogen (e.g., in a silicon nitride) or hafnium and oxygen (e.g., in a hafnium oxide). Etch-stop layers 119 of hafnium and oxygen may have good etch selectivities with dielectric layers and materials of silicon and nitrogen and of silicon and oxygen. Different layers 119 (for example, above or below layer 110) may have the same or different compositions.

FIG. 1B illustrates view 105, including portions of memory region 102, for example, outer and inner electrodes 122, 123 of memory cells 120 in a pair of adjacent stacks 121. Dielectric material 124 is between adjacent stacks 121. Vertical electrodes 123 extend through dielectric layers 119, 129 over dielectric layer 144A. Each stack 121 includes a continuous layer 127 conformally on electrode 123 and dielectric layers 125, between electrodes 122, 123 and between electrodes 122 and layers 125. A dielectric layer 152 may be over each electrode 123.

The lateral (e.g., upper and lower) surfaces 128 of memory cells 120 are at vertical positions H_{A}, none of which are aligned with (e.g., at a same height as) any vertical positions H_{B} of lateral surfaces 118 of any of interconnect lines 111 (at FIG. 1A). Height H₁ of each stack 121 of memory cells 120 spans from a bottom or lower lateral surface 128 (and corresponding vertical position H_{A}) of a lowermost cell 120 of the stack 121 to a top or upper lateral surface 128 (and corresponding vertical position H_{A}) of an uppermost cell 120 of the stack 121.

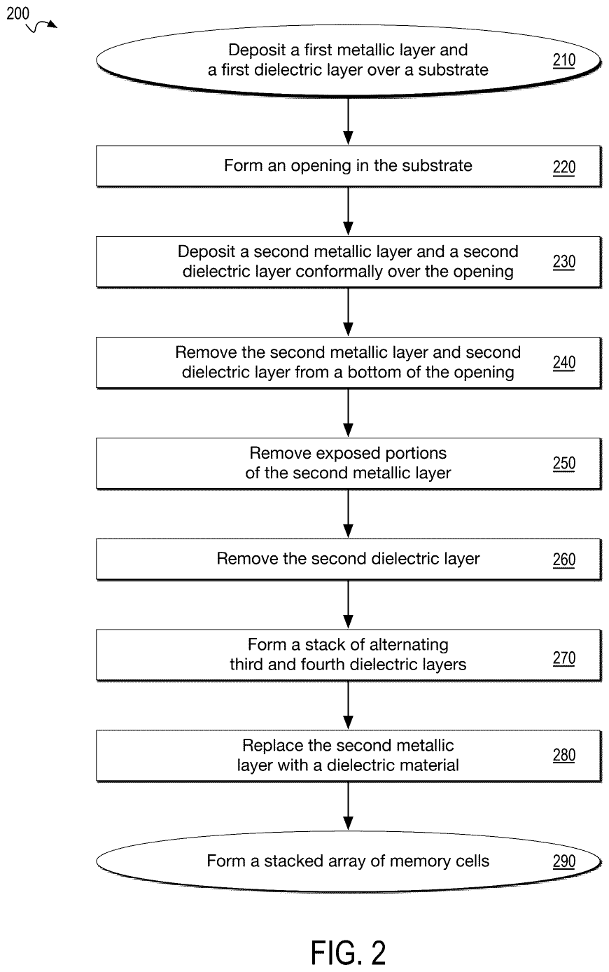

FIG. 2 is a flow chart of methods 200 for forming a memory region with embedded memory stacks and a narrow transition region between the memory region and an adjacent logic region, in accordance with some embodiments. Methods 200 include operations 210-290. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, multiple openings may be formed before depositing metallic and dielectric layers over the opening(s). Some operations may be included within other operations so that the number of operations illustrated FIG. 2 is not a limitation of the methods 200.

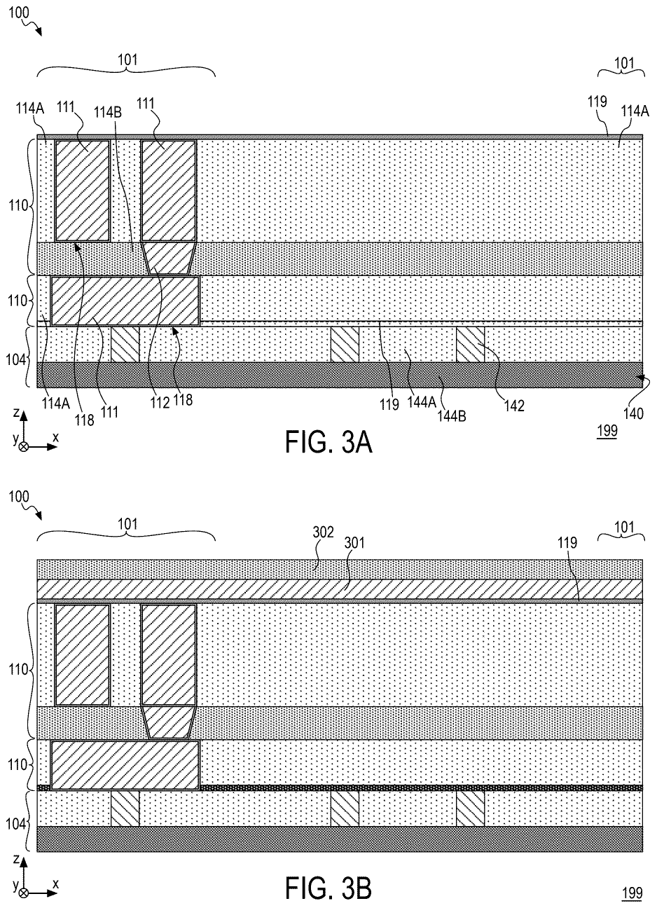

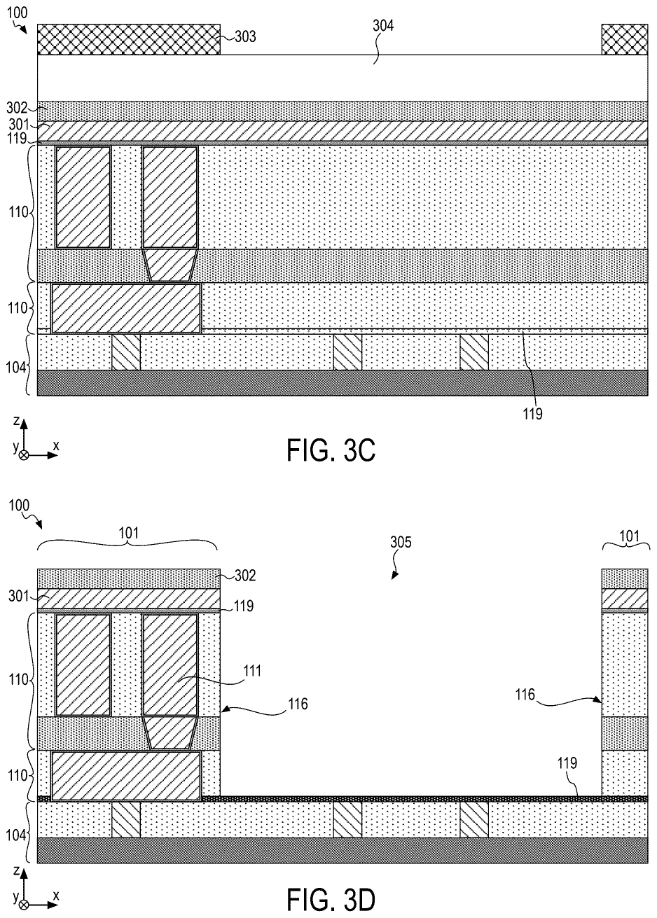

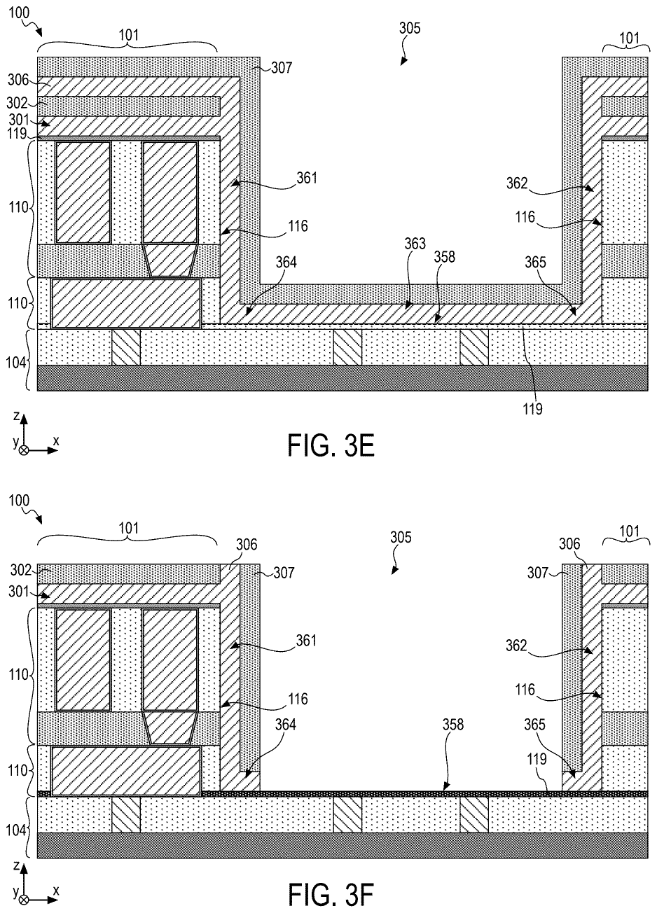

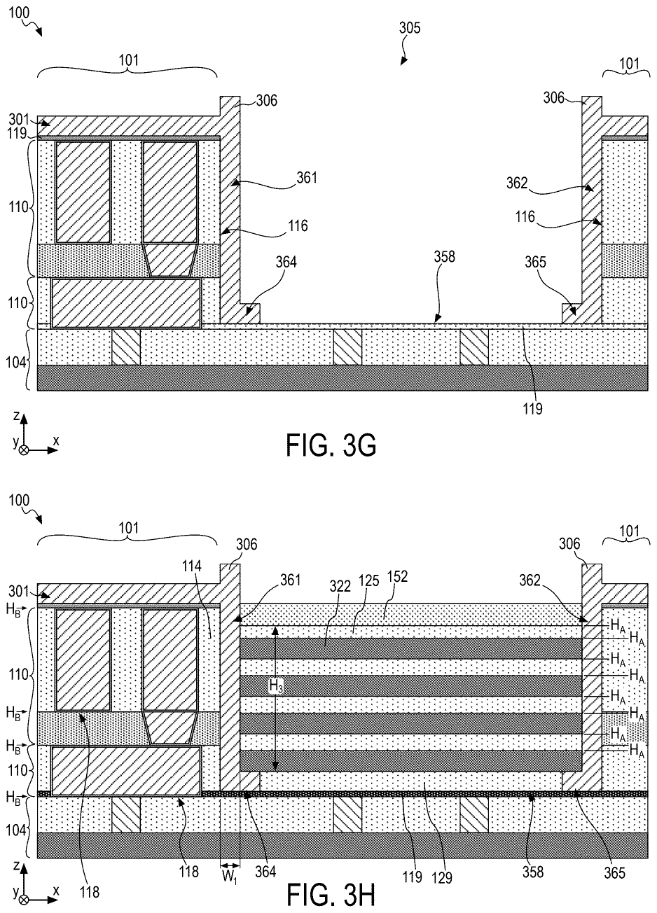

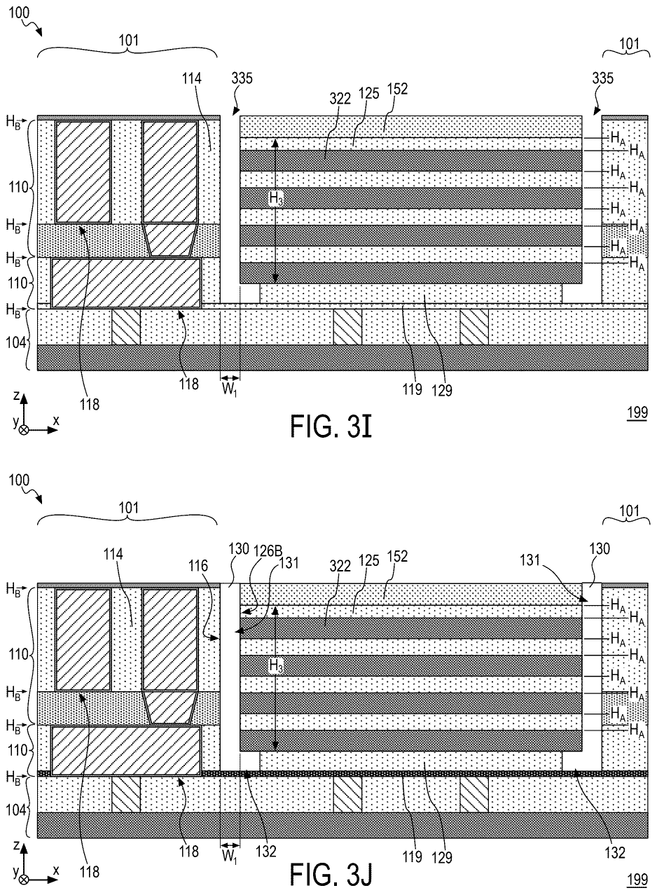

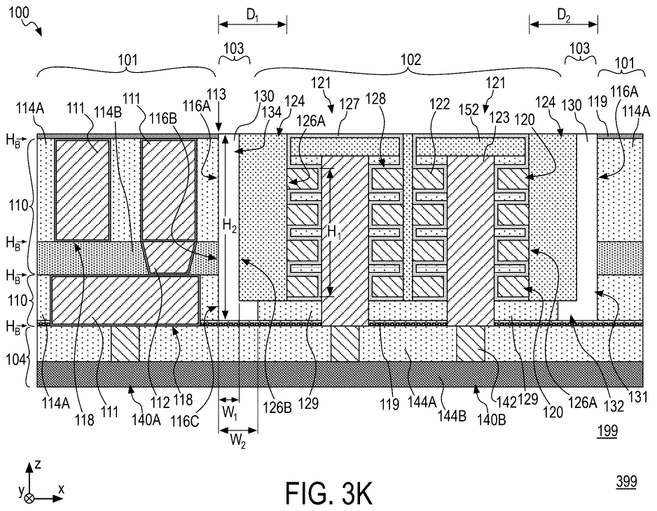

FIGS. 3A, 3B, 3C, 3D, 3E, 3F, 3G, 3H, 3I, 3J, and 3K illustrate profile views of an IC device 100 having memory region 102 with stacks 121 of memory cells 120 and a narrow transition region 103 between logic and memory regions 101, 102, at various stages of manufacture, in accordance with some embodiments. FIGS. 3A-3K show possible examples of intermediate structures during an embodiment of a practice of methods 200 of FIG. 2.

FIG. 3A shows a substrate 199 that includes one or more interconnect layers 110 over device layer 104 in a workpiece or IC device 100, in accordance with some embodiments, for example, following receipt of substrate 199 during a BEOL process. Substrate 199 may be an IC substrate 199, such as an IC die or wafer, e.g., much as described of substrate 199 at FIG. 1A.

Substrate 199 includes interconnect lines 111 and vias 112 through dielectric material(s) 114 in logic region 101. Device layer 104 may include transistor structures 140, e.g., in layer 144B, coupled with lines 111 and vias 112 in layers 110 by lines or vias 142, e.g., in layer 144A. Stop layer 119 is over (or at a top of) uppermost layer 110.

Returning to FIG. 2, methods 200 begin at operation 210 with depositing a (chemically) metallic layer over the substrate. In many embodiments, a dielectric layer is deposited over the metallic layer. The metallic layer may be deposited over the substrate first, for example, on exposed dielectric materials (e.g., of an interconnect or etch-stop layer). The dielectric layer may then be deposited over the metallic layer, e.g., to cover the metallic layer during some subsequent operations.

The metallic and dielectric layers may be deposited by any suitable means, for example, blanket deposited over the entire substrate. In many embodiments, the metallic and dielectric layers are deposited by a chemical vapor deposition (CVD).

The metallic and dielectric layers may be of any suitable materials. The metallic layer may be chemically metallic (not necessarily an electrical conductor), e.g., to serve as a non-preferential growth material during a subsequent dielectric deposition. In some embodiments, the metallic layer includes tungsten or both titanium and nitrogen (e.g., in a titanium nitride). In some embodiments, the metallic layer includes amorphous silicon. Other materials may be used.

Some materials (such as amorphous silicon and titanium nitride) may be sufficiently transparent to allow for substrate alignment following full-substrate deposition. Other materials (such as tungsten) may not be transparent and may need to be removed in certain areas of a substrate (e.g., over alignment marks, often in a die frame area). In some embodiments, the metallic material (e.g., tungsten) is selectively removed (e.g., patterned) and replaced with a (transparent) dielectric (e.g., an alignment window), while most of the metallic layer is retained. In embodiments, a dielectric stack is selectively deposited over exposed dielectric material in openings in metallic layers (e.g., at operation 270 of methods 200). In some such embodiments (e.g., with dielectric alignment windows), the dielectric stack is deposited in undesired areas (e.g., over alignment windows) and is removed. Undesired dielectric stacks may be removed by any suitable means. For example, overburden may be blanket deposited (e.g., a silicon oxide deposited to a thickness three times or more of the height of the dielectric stack) and removed by CMP (chemical-mechanical planarization or polish). The polish may remove all material over the substrate down to a particular material layer, e.g., a stop layer deposited before the metallic layer (such as layer 119, as described in FIGS. 1A, 3A, etc., or a layer deposited over layer 119).

Suitable materials for the dielectric layer may provide sufficient masking for, and differentiation from, the metallic layer, for example, during a subsequent planarization or etch operation that removes a second metallic layer over this dielectric layer. In many embodiments, the dielectric layer includes silicon and nitrogen (e.g., in a silicon nitride). Other materials may be used.

FIG. 3B shows metallic and dielectric layers 301, 302 over substrate 199 in workpiece or device 100, in accordance with some embodiments, for example, following a performance of depositing operation 210. Metallic layer 301 is over dielectric layer 302. Layers 301, 302 are over interconnect layers 110. In the exemplary embodiment of FIG. 3B, layer 302 is on an etch-stop layer 119. In many embodiments, metallic layer 301 includes tungsten, both titanium and nitrogen, or amorphous silicon. In many embodiments, dielectric layer 302 includes silicon and nitrogen

Returning to FIG. 2, methods 200 continue at operation 220 with forming an opening in the one or more interconnect layers. The opening may be adjacent one or more interconnect lines in the one or more interconnect layers. For example, the opening may be made down through dielectric material of the interconnect layer(s) (as well as through metallic and dielectric layers deposited at operation 210), but in a region without any formed interconnect lines or vias, such that the dielectric material is retained between the interconnect lines or vias and the opening (e.g., forming a sidewall of the opening). The opening may be formed by any suitable means, for example, an anisotropic etch through a photolithographically patterned mask. The opening may be formed down to a suitable depth, e.g., to accommodate a stack of memory cells, and may stop on a material having an etch-selectivity with the dielectric material of the interconnect layers, such as an etch-stop layer.

FIG. 3C shows upper and lower mask layers 303, 304 over metallic and dielectric layers 301, 302 in workpiece or device 100, in accordance with some embodiments, for example, during a performance of forming operation 220. Mask layer 303 may be a photoresist layer 303, e.g., patterned to provide an opening for a subsequent etch. Mask layer 304 may include one or more of an inorganic anti-reflective coating (ARC) layer, an organic ARC layer, and a hard-mask layer.

FIG. 3D shows opening 305 in interconnect layers 110 in workpiece or device 100, in accordance with some embodiments, for example, following a performance of forming operation 220. Opening 305 is in interconnect layers 110 and adjacent interconnect lines 111 and via 112. Opening 305 has multiple sidewalls 116 (e.g., sidewalls 116 of interconnect layers 110). Opening 305 is through multiple interconnect layers 110 and down to an etch-stop layer 119.

Returning to FIG. 2, methods 200 continue by depositing a second metallic layer and a second dielectric layer over the opening at operation 230. The second metallic layer and second dielectric layer may be deposited conformally over the opening, e.g., over sidewalls on both sides of (e.g., and surrounding) the opening. For example, a first portion of the second metallic layer may be conformally deposited on a first sidewall and a second portion of the second metallic layer may be conformally deposited on an opposing, second sidewall. The second dielectric layer may be conformally deposited over both the first and second portions of the second metallic layer.

The conformal deposition of the second metallic layer may also deposit the second metallic layer (e.g., a third portion of the second metallic layer) on a bottom surface of the opening, between the first and second portions of the second metallic layer. The second metallic layer and second dielectric layer may be deposited completely over the bottom surface of the opening, e.g., with the second metallic layer continuous between the first and second portions of the second metallic layer. For example, fourth and fifth portions of the second metallic layer are deposited on the bottom surface of the opening, and the second metallic layer is continuous between the first and fourth portions of the second metallic layer, between the fourth and third portions, between the third and fifth portions, and between the fifth and second portions of the second metallic layer. The second metallic layer and second dielectric layer may be conformally deposited over the entire field of the substrate, including over the one or more interconnect lines in the one or more interconnect layers.

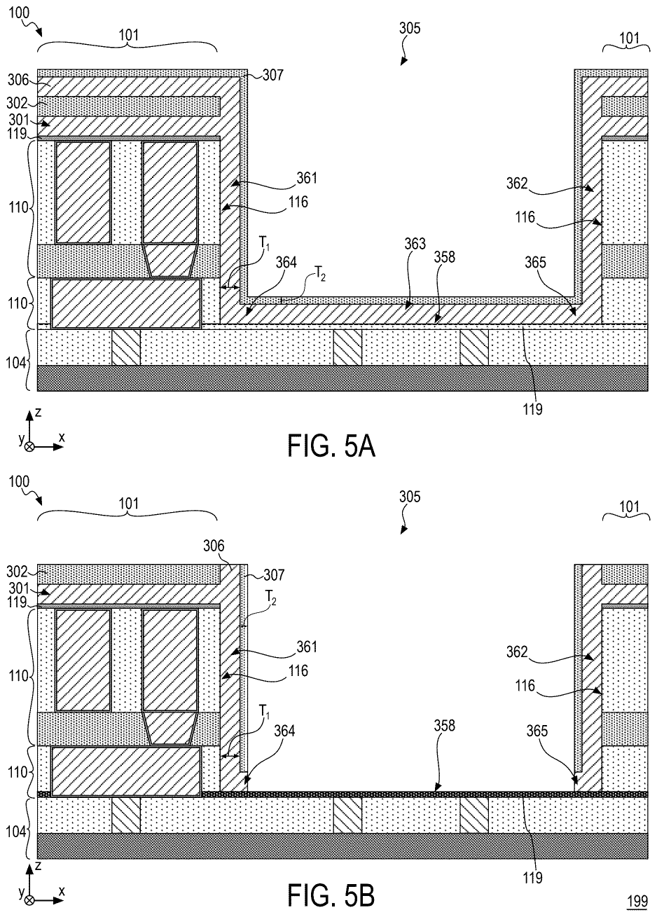

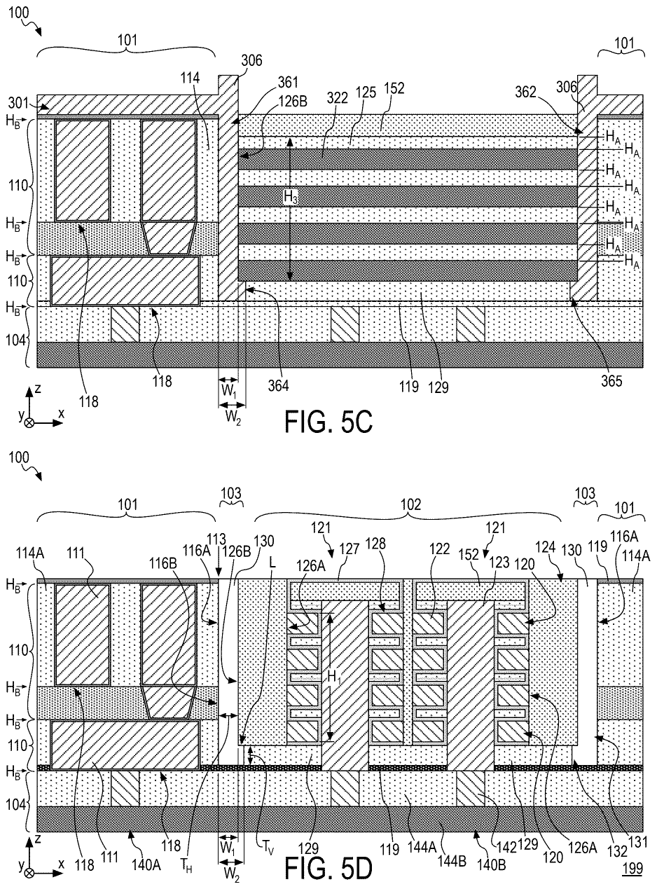

The thickness of the deposited second dielectric layer on the sidewalls may determine a width of a subsequently formed transition region. For example, a thin second dielectric layer may enable a narrow transition region, e.g., as described at FIGS. 5A-5D.

The second metallic and dielectric layers may be deposited by any suitable means, for example, blanket deposited over the entire substrate. In many embodiments, the second metallic and dielectric layers are deposited by CVD or an ALD. The second metallic and dielectric layers may be of any suitable materials, for example, the same or different materials as the first metallic and dielectric layers. In many embodiments, the second metallic layer includes amorphous silicon, tungsten, or both titanium and nitrogen (e.g., in a titanium nitride). In many embodiments, the second dielectric layer includes silicon and nitrogen (e.g., in a silicon nitride). Other materials may be used.

FIG. 3E shows second metallic and dielectric layers 306, 307 over opening 305 in workpiece or device 100, in accordance with some embodiments, for example, following a performance of depositing operation 230. Second metallic layer 306 is on sidewalls 116. Second dielectric layer 307 is over layer 306. First and second portions 361, 362 of layer 306 are on sidewalls 116. Portions 363, 364, 365 of layer 306 are on a bottom surface 358 of opening 305 (e.g., on layer 119). The fourth portion 364 of layer 306 is continuous with first portion 361. The fifth portion 365 of layer 306 is continuous with second portion 362. The second metallic layer 306 is continuous between first and second portions 361, 362 of layer 306. For example, fourth and fifth portions 364, 365 of layer 306 are deposited on bottom surface 358 of opening 305 (e.g., on layer 119), and layer 306 is continuous between first and fourth portions 361, 364, between fourth and third portions 364, 363, between third and fifth portions 363, 365, and between fifth and second portions 365, 362 of second metallic layer 306.

Returning to FIG. 2, methods 200 continue with removing the second dielectric layer and (the third portion of) the second metallic layer from the bottom surface of the opening at operation 240. In many embodiments, the second dielectric and metallic layers are removed from the bottom surface of the opening with a dry, anisotropic etch. In some such embodiments, the removing the second dielectric and metallic layers from the bottom surface of the opening retains the second dielectric layer and the first and second portions of the second metallic layer on the first and second sidewalls of the opening. In many embodiments, the removing the second dielectric and metallic layers from the bottom surface of the opening also removes the second metallic layer and the second dielectric layer from over the one or more interconnect lines in the one or more interconnect layers.

FIG. 3F shows second metallic and dielectric layers 306, 307 on sidewalls 116 of opening 305 and layers 306, 307 absent on bottom surface 358 of opening 305 (e.g., exposed upper surface 358 of layer 119) in workpiece or device 100, in accordance with some embodiments, for example, following a performance of removing operation 240. Portions 361, 362 are on opposing sidewalls 116 of opening 305. Portions 364, 365 are on bottom surface 358 of opening 305. Portions 361, 364 of second metallic layer 306 are continuous, and portions 362, 365 of second metallic layer 306 are continuous. Layer 306 is substantially covered by layer 307 (e.g., with only ends of portions 361, 364, 362, 365 exposed).

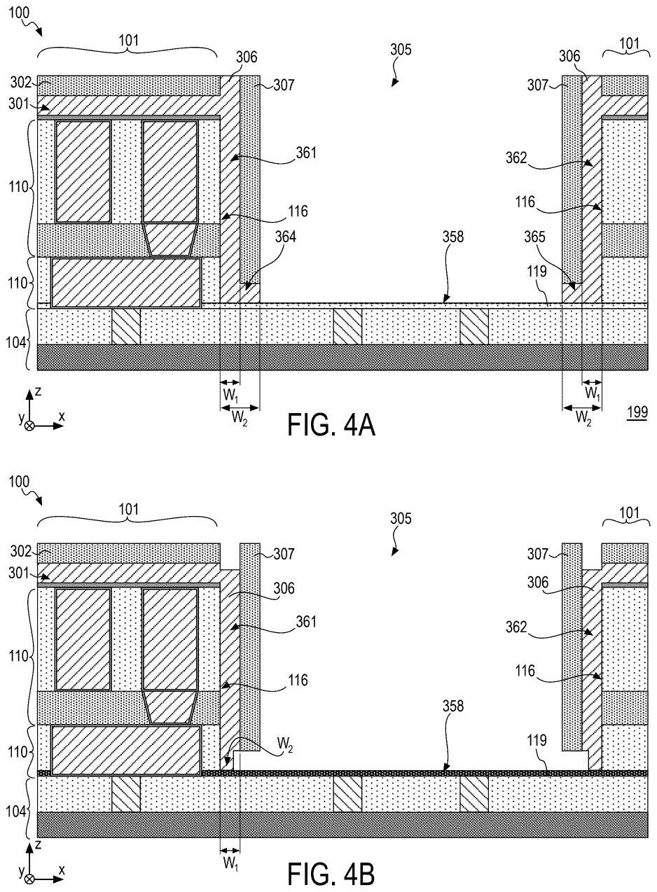

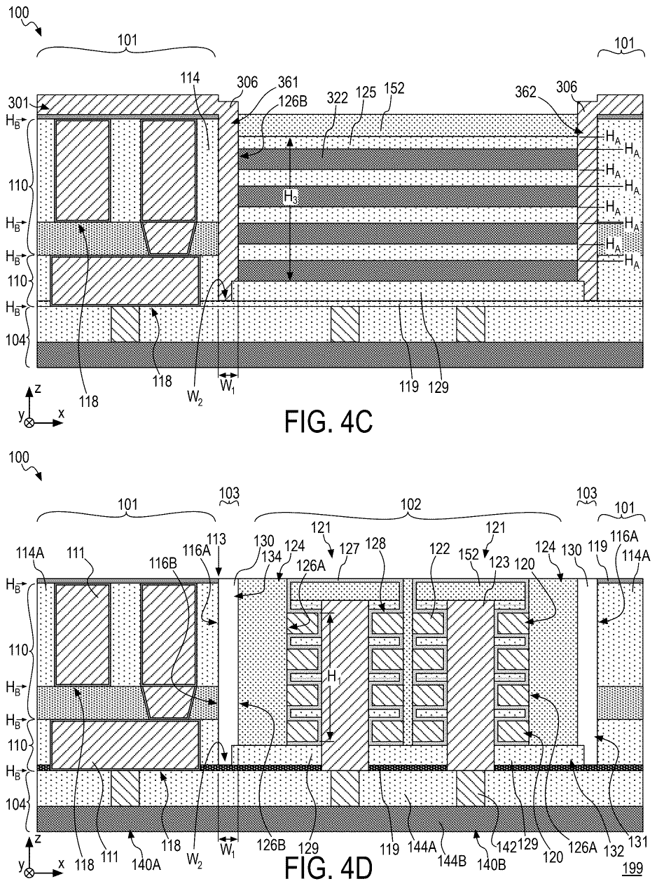

Returning to FIG. 2, methods 200 continue at operation 250 by removing the fourth and fifth portions of the second metallic layer by isotropically etching the second metallic layer and retaining the first and second portions of the second metallic layer. Operation 250 is described further at FIGS. 4A, 4B, and 4C.

Methods 200 continue at operation 260 with exposing the first and second portions of the second metallic layer. In many embodiments, exposing the first and second portions of the second metallic layer also exposes the first metallic layer. The first and second portions of the second metallic layer may be exposed by any suitable means. In many embodiments, the first and second portions of the second metallic layer are exposed by removing the second dielectric layer. The second dielectric layer(s) may be removed by any suitable means. In many embodiments, the second dielectric layer(s) are removed with a selective, isotropic etch. In many embodiments, removing the second dielectric layer also removes the first dielectric layer.

FIG. 3G shows surface 358 of dielectric layer 119 at a bottom of opening 305 (and metallic layers 301, 306 elsewhere) exposed in workpiece or device 100, in accordance with some embodiments, for example, following a performance of exposing operation 260. Substrate 199 is prepared for a formation of a DoD stack in opening 305, e.g., with a preferential growth surface 358 of dielectric layer 119 exposed at a bottom of opening 305 and non-preferential growth surfaces elsewhere. With the exception of exposed dielectric surface 358, metallic layers 301, 306 provide non-preferential growth surfaces over the entirety of substrate 199. Metallic layers 301 cover most of the lateral surfaces of substrate 199, e.g. outside of opening 305, for example, to ensure that no dielectric is deposited outside of opening 305 in a DoD process. Metallic layers 306 cover sidewalls 116 of opening 305, for example, to ensure a dielectric stack may be built up from bottom surface 358 of opening 305 in a DoD process without (e.g., conformal) growth on sidewalls 116 interfering.

Returning to FIG. 2, methods 200 continue by forming a stack of alternating third and fourth dielectric layers between the first and second portions of the second metallic layer at operation 270. The third and fourth dielectric layers may be, respectively, scaffolding layers (e.g., between memory cells) and sacrificial layers (e.g., to be replaced by memory cells). The stack of alternating third and fourth dielectric layers may be formed by any suitable means. In many embodiments, the stack of alternating third and fourth dielectric layers is formed by a DoD process. For example, third and fourth dielectric layers may be deposited, one after the other, one over the other, by an ALD process to form the stack of alternating third and fourth dielectric layers. The DoD process preferentially (e.g., selectively) deposits the dielectric layers on exposed dielectric growth (e.g., seed) surfaces and does not deposit on exposed chemically metallic surfaces. In some embodiments, during the deposition operation, a reactant forms an inhibitor (e.g., an organosilane-based molecule, such as TMCS (trimethylchlorosilane, trimethylsilyl chloride, or chlorotrimethylsilane) or HMDS (hexamethyldisilazane or bis(trimethylsilyl)amine), or an organic self-assembled monolayer) on any exposed metallic surfaces that impedes dielectric growth on the metallic surfaces.

The DoD process enables the formation of the layer stack up from the dielectric bottom of the opening without forming the stack laterally (e.g., conformally) from the metallic sidewalls, which enables growing the stack of layers much more closely to the adjacent interconnect lines and layers of the logic region than would be typically feasible. In many embodiments, the stack of alternating third and fourth dielectric layers is formed so close to the interconnect layers of the logic region that the metallic sidewall layers have a width (e.g., between the dielectric material of the interconnect layers and the third and fourth dielectric layers in the stack) less than a height of the stack of alternating third and fourth dielectric layers.

The DoD process also enables the formation of the layer stack without any dependence on (e.g., constraints of, or required relationship with) the dimensions of the interconnect layer dielectric material(s). In many embodiments, the formation of the third and fourth dielectric layers forms the third and fourth dielectric layers not aligned with any of the interconnect lines in the logic-region interconnect layers.

The third and fourth dielectric layers may be of any suitable materials, for example, dielectric third layers and sacrificial fourth layers having an etch selectivity with the third layers. The third layers may provide electrical isolation between memory cells in the eventual embedded stacked arrays. In many embodiments, the third dielectric layers are of a low-k dielectric material, e.g., including silicon and oxygen (such as silicon oxide, SiO₂). The third dielectric layers in the stack may be much as described of layers 125 (e.g., at FIG. 1A, etc.). In many embodiments, the fourth dielectric layers include silicon and nitrogen (e.g., in a nitride of silicon).

FIG. 3H shows a stack of alternating layers 125, 322 between metallic layers 306 in workpiece or device 100, in accordance with some embodiments, for example, following a performance of forming operation 270. Lateral width W₁ of layers 306 is less than height H₃ of the stack of alternating third and fourth dielectric layers 125, 322 (e.g., less than half of height H₃ of the stack of layers 125, 322). The lateral (e.g., upper and lower) surfaces of layers 125, 322 are at vertical positions H_{A}, none of which are aligned with (e.g., at a same height as) any vertical positions H_{B} of lateral surfaces 118 of any of interconnect lines 111. In many embodiments, third dielectric layers 125 include silicon and oxygen. In many embodiments, fourth dielectric layers 322 include silicon and nitrogen.

Returning to FIG. 2, methods 200 continue with replacing the first and second portions of the second metallic layer with a dielectric material at operation 280. In many embodiments, an opening for the dielectric material is formed by removing the second metallic layer. In some embodiments, removing the second metallic layer (e.g., by an isotropic, selective etch) removes the first metallic layer. In many embodiments, the dielectric material is deposited (e.g., by ALD) in the opening formed by removing the second metallic layer. In some embodiments, the dielectric material is deposited over the substrate (e.g., outside of the opening), and excess dielectric material is removed (e.g., by CMP). In some such embodiments, removing (e.g., polishing off) the excess dielectric material deposited at operation 280 also removes other excess dielectric material (such as inadvertent or undesired deposition of the dielectric stack outside of the opening, as discussed at operation 210, e.g., over an alignment window). In some embodiments, the deposited dielectric material includes silicon and oxygen (e.g., in a low-k oxide of silicon). The deposited dielectric material may be much as described of dielectric material 134 (e.g., at FIG. 1A, etc.).

FIG. 3I shows openings 335 between interconnect layers 110 (e.g., dielectric materials 114) and stacks of layers 125, 322 in workpiece or device 100, in accordance with some embodiments, for example, during a performance of replacing operation 280. There are no metallic layers over interconnect layers 110 or between interconnect layers 110 and stacked layers 125, 322.

FIG. 3J shows dielectric structure(s) 130 between interconnect layers 110 (e.g., dielectric materials 114) and stacks of layers 125, 322 in workpiece or device 100, in accordance with some embodiments, for example, following a performance of replacing operation 280. Lateral width W₁ of structure(s) 130 between sidewalls 116, 126B is less than height H₃ of the stack of alternating third and fourth dielectric layers 125, 322 (e.g., less than half of height H₃ of the stack of layers 125, 322).

Returning to FIG. 2, methods 200 continue at operation 290 by forming a stacked array of memory cells. The stack of memory cells may be formed by any suitable means. In some embodiments, the stack of memory cells is formed by etching through the third and fourth dielectric layers adjacent a stack position (e.g., between the transition region and the stack position), forming the inner electrodes through the third and fourth dielectric layers, etching through the third and fourth dielectric layers to isolate adjacent stacks of memory cells, releasing the sacrificial fourth dielectric layers, conformally depositing a (e.g., ferroelectric) memory insulator layer on the third dielectric layers and inner electrode, and depositing the outer electrodes between the third dielectric layers (e.g., on the memory insulator layer, with the memory insulator layer between the inner and outer electrodes). One or more openings adjacent a stack of memory cells (e.g., between stacks of memory cells) may be filled in with a dielectric material, for example, adjacent a dielectric structure of the transition region between the interconnect layers of a logic region and the stacked memory arrays of the memory region.

The stack formation (e.g., the alternating third and fourth dielectric layers and then the memory cells replacing the sacrificial fourth dielectric layers) may be performed independently of the thickness (or heights or vertical positions of surfaces) of the dielectric layers and interconnect lines in the interconnect layers of the logic region. In many embodiments, the stacked array of memory cells is formed without any alignment of the memory cells with any interconnect lines in the interconnect layers.

FIG. 3K shows IC device 100 having narrow transition region 103 between interconnect layers 110 in logic region 101 and stacks 121 of memory cells 120 in memory region 102, in accordance with some embodiments, for example, following a performance of forming operation 290. The exemplary embodiment of FIG. 3K may be similar to (e.g., exactly the same as) device 100 of FIG. 1A. None of memory cells 120 (e.g., vertical positions H_{A}) are aligned with any of interconnect lines 111 in interconnect layers 110 (e.g., vertical positions H_{B}).

IC device 100 may include or be coupled to a substrate or other host component 399. Host component 399 may be a package substrate, an interposer, an IC die, etc. For example, substrate 199 may be an IC die that includes regions 101, 102, 103 and transistor structures 140 in device layer 104, substrate 199 may be coupled (e.g., soldered or otherwise bonded) to host component 399, and transistor structures 140 may be coupled to a power supply (not shown) through host component 399.

Host component 399 is a planar platform and may include dielectric and metallization structures. Host component 399 mechanically supports and electrically couples one or more IC devices 100. At least one side of host component 399 includes substrate interconnect interfaces for bonding to one or more IC devices 100. IC device 100 may be direct bonded, e.g., hybrid bonded, to host component 399 or otherwise bonded, e.g., by optional solder bumps. The opposite side of host component 399 may include similar interfaces, e.g., copper pads for socketing and/or solder bumps for bonding device 100 to a host component, such as a printed circuit board (PCB). Host component 399 may be any host component with substrate interconnect interfaces, such as a package host component 399 or interposer, etc. Host component 399 may itself be a die. In many embodiments, host component 399 includes organic dielectric(s), such as a resin or other polymer, between metallization layers.

FIGS. 4A, 4B, 4C and 4D illustrate profile views of IC device 100 having a thinner transition region 103 between interconnect layers 110 in logic region 101 and stacks 121 of memory cells 120 in memory region 102, at various stages of manufacture, in accordance with some embodiments. FIGS. 4A-4D show a workpiece or device 100 at various stages of manufacture, e.g., describing removing operation 250 of methods 200, in accordance with some embodiments. FIG. 4A illustrates second metallic and dielectric layers 306, 307 on sidewalls 116 of opening 305 in workpiece or device 100, in accordance with some embodiments, for example, following a performance of removing operation 240 of methods 200. The exemplary embodiment of FIG. 4A may be similar to (e.g., exactly the same as) the workpiece or device 100 described at FIG. 3F. Portions 361, 362 are on opposing sidewalls 116 of opening 305. Portions 364, 365 are on bottom surface 358 of opening 305. Portions 361, 364 of second metallic layer 306 are continuous, and portions 362, 365 of second metallic layer 306 are continuous. Layer 306 is substantially covered by layer 307 (e.g., with only ends of portions 361, 364, 362, 365 exposed). Notably, widths W₂ (e.g., of lateral portions 364, 365) are greater than widths W₁ (e.g., of vertical portions 361, 362).

Returning to FIG. 2, in some embodiments, methods 200 optionally continue at operation 250 by removing the fourth and fifth portions of the second metallic layer. Removing the fourth and fifth portions may trim back the second metallic layer, reducing a lateral thickness from that of wider, horizontal fourth and fifth portions to that of narrower, vertical first and second portions. The second metallic layers may be sacrificial layers that will subsequently be replaced by dielectric structures to isolate an eventual memory region from one or more surrounding logic region(s).

The fourth and fifth portions may be removed by any suitable means. In many embodiments, the fourth and fifth portions are removed by isotropically etching the second metallic layer, for example, with an isotropic etch selective to the metallic layers. In many embodiments, the first and second portions of the second metallic layer are retained.

FIG. 4B shows second dielectric layers 307 on trimmed second metallic layers 306 on sidewalls 116 of opening 305 in workpiece or device 100, in accordance with some embodiments, for example, following a performance of removing operation 250 of methods 200. First and second portions 361, 362 are retained on opposing sidewalls 116 of opening 305. Fourth and fifth portions are absent, not on bottom surface 358 of opening 305. Notably, widths W₂ (e.g., without lateral portions 364, 365) are less than widths W₁ (e.g., of vertical portions 361, 362).

FIG. 4C illustrates a stack of alternating layers 125, 322 between metallic layers 306 in workpiece or device 100, in accordance with some embodiments, for example, following a performance of forming operation 270. The exemplary embodiment of FIG. 4C may be similar to the workpiece or device 100 described at FIG. 3H. Notably, with the narrower widths W₂ of layer 306, layer 129 (between device layer 104 and the stack of layers 125, 322) is longer and extends to under sidewall 126B (where metallic layer 306 abuts the stack of layers 125, 322).

FIG. 4D shows IC device 100 having narrower transition region 103 between interconnect layers 110 in logic region 101 and stacks 121 of memory cells 120 in memory region 102, in accordance with some embodiments, for example, following a performance of forming operation 290. The exemplary embodiment of FIG. 4D may be similar to the workpiece or device 100 described at FIG. 3K. Notably, with the narrower widths W₂ of dielectric structure(s) 130, layer 129 (between device layer 104 and the stack of layers 125, 322) is longer and extends to under sidewall 126B (where dielectric structure 130 abuts dielectric material 124).

Dielectric structure 130 has width W₁ between dielectric materials 114, 124. Dielectric structure 130 has narrower width W₂ adjacent dielectric layer 129. First width W₁ is greater than narrower width W₂.

FIGS. 5A, 5B, 5C, and 5D illustrate profile views of IC device 100 having a thinner transition region 103 between interconnect layers 110 in logic region 101 and stacks 121 of memory cells 120 in memory region 102, at various stages of manufacture, in accordance with some embodiments. FIG. 5A shows second metallic and dielectric layers 306, 307 on sidewalls 116 of opening 305 in workpiece or device 100, in accordance with some embodiments, for example, following a performance of depositing operation 230 of methods 200. The exemplary embodiment of FIG. 5A may be similar to the workpiece or device 100 described at FIG. 3E. Portions 361, 362 are on opposing sidewalls 116 of opening 305. Portions 363, 364, 365 are on layer 119 in opening 305. Layer 306 is covered by layer 307.

Notably, in the exemplary embodiment of FIG. 5A, second dielectric layer 307 is much thinner than in the exemplary embodiment of FIG. 3E. Second metallic layer 306 has a same (e.g., as in FIG. 3E) first thickness T₁ greater than twice a second thickness T₂ of second dielectric layer 307. In some embodiments, the depositing the second metallic layer and the second dielectric layer at operation 230 (e.g., conformally over opposing sidewalls of the opening) deposits the second metallic layer with a first thickness greater than twice a second thickness of the second dielectric layer.

FIG. 5B illustrates second metallic and dielectric layers 306, 307 on sidewalls 116 of opening 305 in workpiece or device 100, in accordance with some embodiments, for example, following a performance of removing operation 240. The exemplary embodiment of FIG. 5B may be similar to the workpiece or device 100 described at FIG. 3F. Notably, with the thinner thickness T₂ of second dielectric layer 307, the retained portions 364, 365 of second metallic layer 306 on bottom surface 358 of opening 305 are shorter (e.g., extending in the x-dimension a distance equal to thickness T₂ of second dielectric layer 307).

FIG. 5C shows a stack of alternating layers 125, 322 between metallic layers 306 in workpiece or device 100, in accordance with some embodiments, for example, following a performance of forming operation 270. The exemplary embodiment of FIG. 5C may be similar to the workpiece or device 100 described at FIG. 3H. Notably, with the shorter retained portions 364, 365 of second metallic layer 306 on bottom surface 358, layer 129 is longer, and width W₂ is shorter between dielectric material 114 and layer 129.

FIG. 5D illustrates IC device 100 having narrower transition region 103 between interconnect layers 110 in logic region 101 and stacks 121 of memory cells 120 in memory region 102, in accordance with some embodiments, for example, following a performance of forming operation 290. The exemplary embodiment of FIG. 5D may be similar to the workpiece or device 100 described at FIG. 3K. Notably, with the narrower widths W₂ of dielectric structure(s) 130, layer 129 is longer.

Vertical portion 131 of dielectric structure 130 has a lateral thickness T_{H} (e.g., in the x-dimension). Horizontal portion 132 of structure 130 has a vertical thickness T_{V} (e.g., in the z-dimension). Thickness T_{V} is approximately equal to thickness T_{H}. Horizontal portion 132 extends a length L beyond vertical portion 131 (e.g., in the x-dimension). Length L (e.g., width W₂ minus width W₁) is less than half of thickness T_{H}.

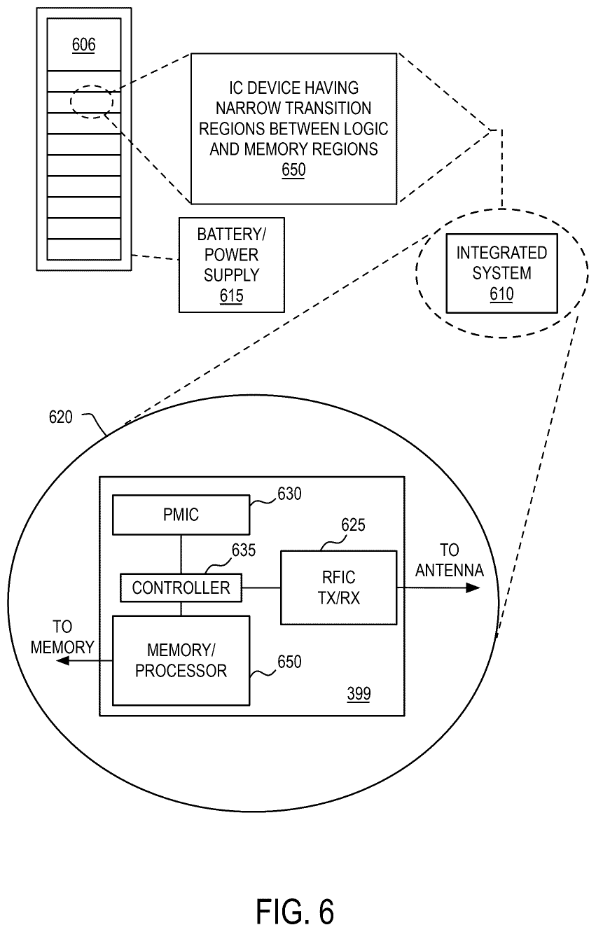

FIG. 6 illustrates a diagram of an example data server machine 606 employing an IC device having narrow transition regions between logic and memory regions, in accordance with some embodiments. Server machine 606 may be any commercial server, for example, including any number of high-performance computing platforms disposed within a rack and networked together for electronic data processing, which in the exemplary embodiment includes one or more devices 650 having narrow transition regions between logic and memory regions.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having narrow transition regions between logic and memory regions, as discussed herein. Device 650 may be further coupled to (e.g., communicatively coupled to) a board, an interposer, or other substrate or host component 399 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 have narrow transition regions between logic and memory regions.

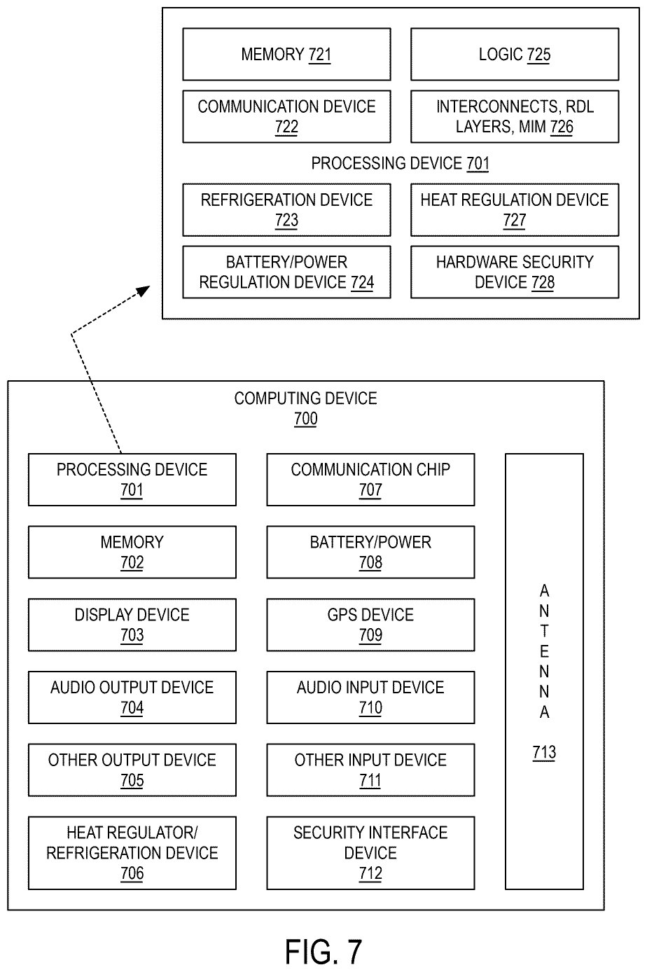

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes one or more interconnect lines or vias in one or more interconnect layers over a device layer, a first of the one or more interconnect lines or vias extending through a dielectric material over the device layer, and a stack of memory cells and dielectric layers over the device layer and laterally adjacent the one or more interconnect layers, the dielectric layers interleaved with the memory cells, a conductor extending vertically through the memory cells and the dielectric layers, wherein the stack of memory cells and a sidewall of the dielectric material are separated by a distance shorter than a height of the stack of memory cells and dielectric layers, and a lateral surface of a first of the memory cells is at a first vertical position not aligned with a second vertical position of a lateral surface of any of the one or more interconnect lines.

In one or more second embodiments, further to the first embodiments, the dielectric material is a first dielectric material, a second dielectric material is on a sidewall of the stack of memory cells and dielectric layers, and a dielectric structure separating the first and second dielectric materials has a width less than half the height of the stack of memory cells and dielectric layers.

In one or more third embodiments, further to the first or second embodiments, a third vertical position of a second lateral surface of a first of the one or more interconnect lines is not aligned with a fourth vertical position of a lateral surface of any of the memory cells.

In one or more fourth embodiments, further to the first through third embodiments, the dielectric material is a first dielectric material, the height is a first height, a second dielectric material is on a sidewall of the stack of memory cells and dielectric layers, and a dielectric structure separates the first and second dielectric materials and has a second height greater than the first height, the second height spanning at least from a bottom of a first of the one or more interconnect layers to a top of a second of the one or more interconnect layers, the second of the one or more interconnect layers over the first of the one or more interconnect layers.

In one or more fifth embodiments, further to the first through fourth embodiments, the dielectric layers are first dielectric layers, a second dielectric layer is over the device layer, between the device layer and the stack of memory cells and first dielectric layers, the dielectric structure includes a vertical portion between and in contact with both the first and second dielectric materials, and the dielectric structure includes a horizontal portion in contact with the second dielectric layer and the second dielectric material.

In one or more sixth embodiments, further to the first through fifth embodiments, the vertical portion has a lateral thickness in a first direction, the horizontal portion has a vertical thickness in a second direction, orthogonal to the first direction, the vertical thickness approximately equal to the lateral thickness, the horizontal portion extends a length beyond the vertical portion in the first direction, and the length is less than half of the lateral thickness.

In one or more seventh embodiments, further to the first through sixth embodiments, the dielectric layers are first dielectric layers, a second dielectric layer is over the device layer, between the device layer and the stack of memory cells and first dielectric layers, the dielectric structure has a first width between the first and second dielectric materials, the dielectric structure has a second width adjacent the second dielectric layer, and the first width is greater than the second width.

In one or more eighth embodiments, an apparatus includes a logic region including one or more interconnect lines or vias extending through a first dielectric material over a device layer, wherein a border of the logic region includes a first sidewall of the first dielectric material, a memory region over the device layer and laterally adjacent the logic region, the memory region including a second dielectric material and a stack of memory cells, the second dielectric material to both sides of the stack of memory cells, the second dielectric material including second and third sidewalls, the second sidewall on the stack of memory cells, the third sidewall adjacent the logic region, a conductor extending vertically through the memory cells, wherein a first of the memory cells are not vertically aligned with any of the one or more interconnect lines, and a transition region separating the logic and memory regions, the transition region including a third dielectric material between the first and second dielectric materials, the transition region having a width less than half of a height of the stack of memory cells, the width separating fourth and fifth sidewalls of the third dielectric material.

In one or more ninth embodiments, further to the eighth embodiments, a dielectric layer is in the memory region, between the device layer and the stack of memory cells, a dielectric structure includes the third dielectric material in continuous first and second portions, the first portion is between and in contact with the first and second dielectric materials, and the second portion is in contact with the dielectric layer and the second dielectric material.

In one or more tenth embodiments, further to the eighth or ninth embodiments, the first portion has a lateral thickness in a first direction, the second portion has a vertical thickness in a second direction, orthogonal to the first direction, the vertical thickness approximately equal to the lateral thickness, the second portion extends a length beyond the first portion in the first direction, and the length is less than half of the lateral thickness.

In one or more eleventh embodiments, further to the eighth through tenth embodiments, the dielectric structure has a first width between the first and second dielectric materials, the dielectric structure has a second width adjacent the dielectric layer, and the first width is greater than the second width.

In one or more twelfth embodiments, further to the eighth through eleventh embodiments, the stack of memory cells and the first sidewall of the first dielectric material are separated by a distance less than half of the height of the stack of memory cells.

In one or more thirteenth embodiments, a method includes depositing a first metallic layer and a first dielectric layer over a substrate, the first dielectric layer over the first metallic layer, the substrate including one or more interconnect layers over a device layer, forming an opening in the one or more interconnect layers, the opening adjacent one or more interconnect lines in the one or more interconnect layers, depositing a second metallic layer and a second dielectric layer conformally over first and second sidewalls of the opening, the second dielectric layer over a first portion of the second metallic layer on the first sidewall and a second portion of the second metallic layer on the second sidewall, exposing the first and second portions of the second metallic layer by removing the second dielectric layer, forming a stack of alternating third and fourth dielectric layers between the first and second portions of the second metallic layer, and replacing the first and second portions of the second metallic layer with a dielectric material.

In one or more fourteenth embodiments, further to the thirteenth embodiments, the dielectric material is a first dielectric material, the one or more interconnect lines extend through a second dielectric material of the one or more interconnect layers, the first dielectric material has a width between the second dielectric material and the third and fourth dielectric layers, and the width is less than a height of the stack of alternating third and fourth dielectric layers.

In one or more fifteenth embodiments, further to the thirteenth or fourteenth embodiments, the forming the stack of alternating third and fourth dielectric layers forms a first of the third dielectric layers not aligned with any of the one or more interconnect lines in the one or more interconnect layers.

In one or more sixteenth embodiments, further to the thirteenth through fifteenth embodiments, the method also includes forming a stacked array of memory cells, wherein a first of the memory cells is not aligned with any of the one or more interconnect lines in the one or more interconnect layers.

In one or more seventeenth embodiments, further to the thirteenth through sixteenth embodiments, the depositing the second metallic layer and the second dielectric layer conformally over the first and second sidewalls of the opening deposits a third portion of the second metallic layer on a bottom surface of the opening, between the first and second portions of the second metallic layer, and also including removing the second dielectric layer and the third portion of the second metallic layer from the bottom surface of the opening, and retaining the second dielectric layer and the first and second portions of the second metallic layer on the first and second sidewalls of the opening.

In one or more eighteenth embodiments, further to the thirteenth through seventeenth embodiments, the depositing the second metallic layer and the second dielectric layer conformally over the first and second sidewalls of the opening deposits fourth and fifth portions of the second metallic layer on a bottom surface of the opening, the fourth portion of the second metallic layer continuous with the first portion of the second metallic layer, the fifth portion of the second metallic layer continuous with the second portion of the second metallic layer, and also including removing the fourth and fifth portions of the second metallic layer by isotropically etching the second metallic layer, and retaining the first and second portions of the second metallic layer.

In one or more nineteenth embodiments, further to the thirteenth through eighteenth embodiments, the depositing the second metallic layer and the second dielectric layer conformally over the first and second sidewalls of the opening deposits the second metallic layer with a first thickness and the second dielectric layer with a second thickness, and the first thickness is more than twice the second thickness.

In one or more twentieth embodiments, further to the thirteenth through nineteenth embodiments, the dielectric material is a first dielectric material, and the depositing the first metallic layer and the first dielectric layer over the substrate deposits the first metallic layer and the first dielectric layer on a stop layer over the one or more interconnect layers, and also including replacing a sixth portion of the first metallic layer over the substrate with a seventh portion of a second dielectric material, wherein the forming the stack of alternating third and fourth dielectric layers between the first and second portions of the second metallic layer forms the stack of alternating third and fourth dielectric layers over the seventh portion of the second dielectric material, and removing the seventh portion of the second dielectric material and the stack of alternating third and fourth dielectric layers over the seventh portion of the second dielectric material by polishing down to the stop layer.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
one or more interconnect lines or vias in one or more interconnect layers over a device layer, a first of the one or more interconnect lines or vias extending through a dielectric material over the device layer; and
a stack of memory cells and dielectric layers over the device layer and laterally adjacent the one or more interconnect layers, the dielectric layers interleaved with the memory cells, a conductor extending vertically through the memory cells and the dielectric layers, wherein:
the stack of memory cells and a sidewall of the dielectric material are separated by a distance shorter than a height of the stack of memory cells and dielectric layers; and
a lateral surface of a first of the memory cells is at a first vertical position not aligned with a second vertical position of a lateral surface of any of the one or more interconnect lines.

2. The apparatus of claim 1, wherein:
the dielectric material is a first dielectric material;
a second dielectric material is on a sidewall of the stack of memory cells and dielectric layers; and
a dielectric structure separating the first and second dielectric materials has a width less than half the height of the stack of memory cells and dielectric layers.

3. The apparatus of claim 1, wherein a third vertical position of a second lateral surface of a first of the one or more interconnect lines is not aligned with a fourth vertical position of a lateral surface of any of the memory cells.

4. The apparatus of claim 1, wherein:
the dielectric material is a first dielectric material;
the height is a first height;
a second dielectric material is on a sidewall of the stack of memory cells and dielectric layers; and
a dielectric structure separates the first and second dielectric materials and has a second height greater than the first height, the second height spanning at least from a bottom of a first of the one or more interconnect layers to a top of a second of the one or more interconnect layers, the second of the one or more interconnect layers over the first of the one or more interconnect layers.

5. The apparatus of claim 4, wherein:
the dielectric layers are first dielectric layers;
a second dielectric layer is over the device layer, between the device layer and the stack of memory cells and first dielectric layers;
the dielectric structure comprises a vertical portion between and in contact with both the first and second dielectric materials; and
the dielectric structure comprises a horizontal portion in contact with the second dielectric layer and the second dielectric material.

6. The apparatus of claim 5, wherein:
the vertical portion has a lateral thickness in a first direction;
the horizontal portion has a vertical thickness in a second direction, orthogonal to the first direction, the vertical thickness approximately equal to the lateral thickness;
the horizontal portion extends a length beyond the vertical portion in the first direction; and
the length is less than half of the lateral thickness.

7. The apparatus of claim 4, wherein:
the dielectric layers are first dielectric layers;
a second dielectric layer is over the device layer, between the device layer and the stack of memory cells and first dielectric layers;
the dielectric structure has a first width between the first and second dielectric materials;
the dielectric structure has a second width adjacent the second dielectric layer; and
the first width is greater than the second width.

8. An apparatus, comprising:
a logic region comprising one or more interconnect lines or vias extending through a first dielectric material over a device layer, wherein a border of the logic region comprises a first sidewall of the first dielectric material;
a memory region over the device layer and laterally adjacent the logic region, the memory region comprising a second dielectric material and a stack of memory cells, the second dielectric material to both sides of the stack of memory cells, the second dielectric material comprising second and third sidewalls, the second sidewall on the stack of memory cells, the third sidewall adjacent the logic region, a conductor extending vertically through the memory cells, wherein a first of the memory cells are not vertically aligned with any of the one or more interconnect lines; and
a transition region separating the logic and memory regions, the transition region comprising a third dielectric material between the first and second dielectric materials, the transition region having a width less than half of a height of the stack of memory cells, the width separating fourth and fifth sidewalls of the third dielectric material.

9. The apparatus of claim 8, wherein:
a dielectric layer is in the memory region, between the device layer and the stack of memory cells;
a dielectric structure comprises the third dielectric material in continuous first and second portions;
the first portion is between and in contact with the first and second dielectric materials; and
the second portion is in contact with the dielectric layer and the second dielectric material.

10. The apparatus of claim 9, wherein:
the first portion has a lateral thickness in a first direction;
the second portion has a vertical thickness in a second direction, orthogonal to the first direction, the vertical thickness approximately equal to the lateral thickness;
the second portion extends a length beyond the first portion in the first direction; and
the length is less than half of the lateral thickness.

11. The apparatus of claim 9, wherein:
the dielectric structure has a first width between the first and second dielectric materials;
the dielectric structure has a second width adjacent the dielectric layer; and
the first width is greater than the second width.

12. The apparatus of claim 11, wherein the stack of memory cells and the first sidewall of the first dielectric material are separated by a distance less than half of the height of the stack of memory cells.

13. A method, comprising:
depositing a first metallic layer and a first dielectric layer over a substrate, the first dielectric layer over the first metallic layer, the substrate comprising one or more interconnect layers over a device layer;
forming an opening in the one or more interconnect layers, the opening adjacent one or more interconnect lines in the one or more interconnect layers;
depositing a second metallic layer and a second dielectric layer conformally over first and second sidewalls of the opening, the second dielectric layer over a first portion of the second metallic layer on the first sidewall and a second portion of the second metallic layer on the second sidewall;
exposing the first and second portions of the second metallic layer by removing the second dielectric layer;
forming a stack of alternating third and fourth dielectric layers between the first and second portions of the second metallic layer; and
replacing the first and second portions of the second metallic layer with a dielectric material.

14. The method of claim 13, wherein:
the dielectric material is a first dielectric material;
the one or more interconnect lines extend through a second dielectric material of the one or more interconnect layers;
the first dielectric material has a width between the second dielectric material and the third and fourth dielectric layers; and
the width is less than a height of the stack of alternating third and fourth dielectric layers.

15. The method of claim 13, wherein the forming the stack of alternating third and fourth dielectric layers forms a first of the third dielectric layers not aligned with any of the one or more interconnect lines in the one or more interconnect layers.

16. The method of claim 15, further comprising forming a stacked array of memory cells, wherein a first of the memory cells is not aligned with any of the one or more interconnect lines in the one or more interconnect layers.

17. The method of claim 13, wherein the depositing the second metallic layer and the second dielectric layer conformally over the first and second sidewalls of the opening deposits a third portion of the second metallic layer on a bottom surface of the opening, between the first and second portions of the second metallic layer, and further comprising:
removing the second dielectric layer and the third portion of the second metallic layer from the bottom surface of the opening; and
retaining the second dielectric layer and the first and second portions of the second metallic layer on the first and second sidewalls of the opening.

18. The method of claim 13, wherein the depositing the second metallic layer and the second dielectric layer conformally over the first and second sidewalls of the opening deposits fourth and fifth portions of the second metallic layer on a bottom surface of the opening, the fourth portion of the second metallic layer continuous with the first portion of the second metallic layer, the fifth portion of the second metallic layer continuous with the second portion of the second metallic layer, and further comprising:
removing the fourth and fifth portions of the second metallic layer by isotropically etching the second metallic layer; and
retaining the first and second portions of the second metallic layer.

19. The method of claim 13, wherein:
the depositing the second metallic layer and the second dielectric layer conformally over the first and second sidewalls of the opening deposits the second metallic layer with a first thickness and the second dielectric layer with a second thickness; and
the first thickness is more than twice the second thickness.

20. The method of claim 13, wherein:
the dielectric material is a first dielectric material; and
the depositing the first metallic layer and the first dielectric layer over the substrate deposits the first metallic layer and the first dielectric layer on a stop layer over the one or more interconnect layers; and
further comprising:
replacing a sixth portion of the first metallic layer over the substrate with a seventh portion of a second dielectric material, wherein the forming the stack of alternating third and fourth dielectric layers between the first and second portions of the second metallic layer forms the stack of alternating third and fourth dielectric layers over the seventh portion of the second dielectric material; and
removing the seventh portion of the second dielectric material and the stack of alternating third and fourth dielectric layers over the seventh portion of the second dielectric material by polishing down to the stop layer.
